(19) United States
(12) Patent Application Publication
(10) Pub. No.: US 2005/0134149 A1
(43) Pub. Date: Jun. 23, 2005

(54) Piezoelectric vibration energy harvesting device

(76) Inventors: Ken Kan Deng, N. Potomac, MD (US); Kikmet Andic, Baltimore, MD (US)

Correspondence Address: BLANK ROME LLP, 600 NEW HAMPSHIRE AVENUE, N.W., WASHINGTON, DC, 20037, US

(21) Appl. No.: 11/031,993

(22) Filed: Jan. 11, 2005

Related U.S. Application Data
(63) Continuation-in-part of application No. 10/887,216, filed on Jul. 9, 2004.
(60) Provisional application No. 60/486,172, filed on Jul. 11, 2003.

(51) Int. Cl. H01L 41/113

(52) U.S. Cl. 310/339

(57) ABSTRACT

A piezoelectric vibration energy harvesting device which is made up of a first mass, a second, a first spring coupled to the first mass, and a second spring coupled to the second mass. A piezoelectric element is bonded between the first mass and the second spring, so that a stress applied to the second spring is applied to the piezoelectric element

### RELATED APPLICATIONS

This application is a continuation-in-part of co-pending U.S. patent application Ser. No. 10/887,216 to Ken K. Deng, filed Jul. 9, 2004, which claims the benefit of U.S. Provisional Patent Application Ser. No. 60/486,172, filed Jul. 11, 2003, the subject matter of both of which is incorporated by reference herein.

### STATEMENT OF GOVERNMENT INTEREST

The work leading to the present invention was supported in part by Naval Surface Warfare Center Dahlgren Division (NSWCDD) Contract Number: N00178-03-C-3056. The government has certain rights in the invention.

### FIELD OF THE INVENTION

The present invention is directed to a highly efficient, small size, vibration harvesting and electric energy storage device. The energy level is high enough to power a wireless sensor.

### BACKGROUND OF THE INVENTION

Current technology for harvesting energy utilizes a flexural, piezoelectric composite bending structure as a vibration energy to electric energy transducer. Most conventional harvesting devices are single degree-of-freedom (SDOF) systems. The selected piezoelectric materials are PZT ceramics or PVDF polymer. The output of this device is connected to an AC-DC converter which is typically composed of a diode rectifier with a storage capacitor.

A conventional flexural mode piezoelectric effect (d₃₁ mode) is very inefficient resulting in a low conversion efficiency from vibrational energy to electrical energy (less than 10%). Additionally, flexural mode piezoelectric structures are bulky and not suitable for a high frequency vibration condition. SDOF devices have a single resonance peak, at which the harvested energy reaches the highest conversion efficiency. However, the bandwidth of a SDOF system is narrow, thereby limiting its applications. Additionally, most conventional harvesting devices use bulky discrete inductors for impedance matching with the capacitive piezoelectric element of the device. These drawbacks make the conventional devices impractical for many applications.

### SUMMARY OF THE INVENTION

It is therefore an object of the invention to efficiently harvest vibrational kinetic energy from the ambient environment or machinery and store it in the form of electrical energy, which later is used to power an electronic device. A highly efficient, small size vibration harvesting device will enable a self-powered, truly wireless transducer system.

In accordance with an embodiment of the present invention, by using the state-of-the-art relaxor single crystal, which exhibits the highest piezoelectric coupling coefficient, and a compression-tension piezoelectric composite, cymbal structure, a compact, highly efficient vibration energy extracting device is accomplished. Moreover, before connecting a stack including a piezoelectric element disposed between two cymbal-shaped caps, with a rectifier/storage circuit, an inductor L is introduced which is parallel with the piezoelectric stack. The resonance of the LC loop is tuned around the resonance of the stack. This inductor will greatly improve the electrical energy transferring efficiency.

A major difference between the prior art and the above design is in the piezoelectric transduction structure. Instead of using a flexural plate or beam, the new vibration energy harvesting device uses a composite cymbal stack with a proof mass on top. During vibration, the inertial force is transmitted to the piezoelectric disk through the circular cymbal caps. Then the piezoelectric disk is under both compression and tension stresses (d₃₃+d₃₁ mode). The present invention is therefore more efficient than the prior art where the piezoelectric layer is only subject to in-plane stress (d₃₁ mode). Another major change is the transduction material; a relaxor crystal, which has the highest piezoelectric property, is incorporated in the device. In addition, the electric output from the cymbal stack is connected to an inductor before it is linked to a rectifier. The resonance frequency of the inductor L and piezoelectric crystal Cₓ is tuned to be approximately the same as the mechanical resonance of the cymbal stack. Doing so, the electrical energy flows much efficiently from the harvesting device to the storage capacitor.

The invention allows for a much more efficient vibrational energy harvesting device. It also allows for a very small size.

In accordance with another embodiment of the present invention a multiple degree of freedom dynamic system is provided that has a wide band peak. The wider band of resonating frequency range combined with a more efficient compression mode of piezoelectric material and impedance matching electronics, creates a more versatile and efficient energy harvesting device. In addition, the utilization of a gyrator to synthesize an inductor allows maximum power to be stored into the storage element. A gyrator simulates large coils electronically. A gyrator converts an impedance into its inverse. This allows for replacement of an inductor with a capacitor, two or more amplifiers, and some resistors. The synthesized inductor or gyrator also allows an electronically tunable harvester, in which the harvester can automatically tune itself around the bandwidth where vibrational energy is mostly concentrated by changing the value of the synthesized inductor.

Other objects, advantages and salient features of the invention will become apparent from the following detailed description, which, taken in conjunction with the annexed drawings, discloses preferred embodiments of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 shows an elevational view of a device with a cymbal stack in accordance with a first embodiment of the present invention;

FIGS. 2 and 3 show circuit diagrams of the device of FIG. 1 connected to different rectifiers, with the device of FIG. 1 being represented by an equivalent circuit to the left of the dashed line;

FIG. 4 is a diagram of a device in accordance with a second embodiment of the present invention, showing a two degree of freedom system;

FIG. 5 is a graph showing the frequency response of the electric output from a device utilizing the two degree of freedom system illustrated in FIG. 4;

FIGS. 6-9 are elevational views of different devices incorporating the two degree of freedom system illustrated in FIG. 4;

FIG. 10 is a circuit diagram of a device in accordance with a third embodiment of the present invention showing the addition of a gyrator; and

FIGS. 11 and 12 are exemplary circuit diagrams of the gyrator of the circuit diagram illustrated in FIG. 10.

### DETAILED DESCRIPTION OF THE INVENTION

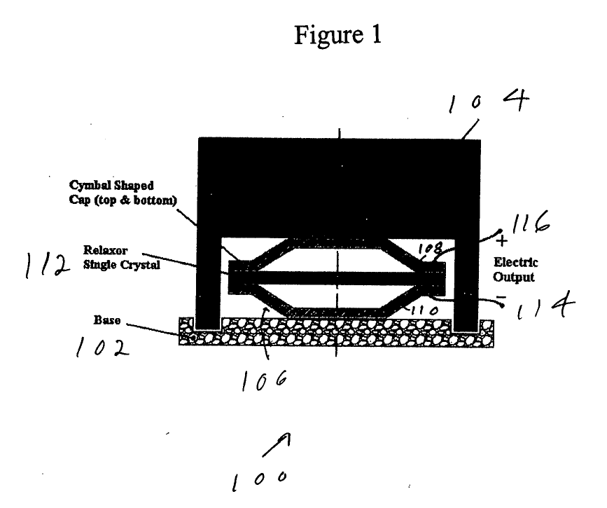

Referring to FIGS. 1-3, FIG. 1 shows an energy harvesting device 100. The device 100 includes a base 102 and a proof mass 104. Disposed between the base 102 and the proof mass 104 is a cymbal stack 106 including top and bottom cymbal-shaped caps 108, 110 sandwiching a relaxor single crystal 112. The cymbal-shaped caps 108, 110 are connected to electrodes 114, 116 forming an electric output.

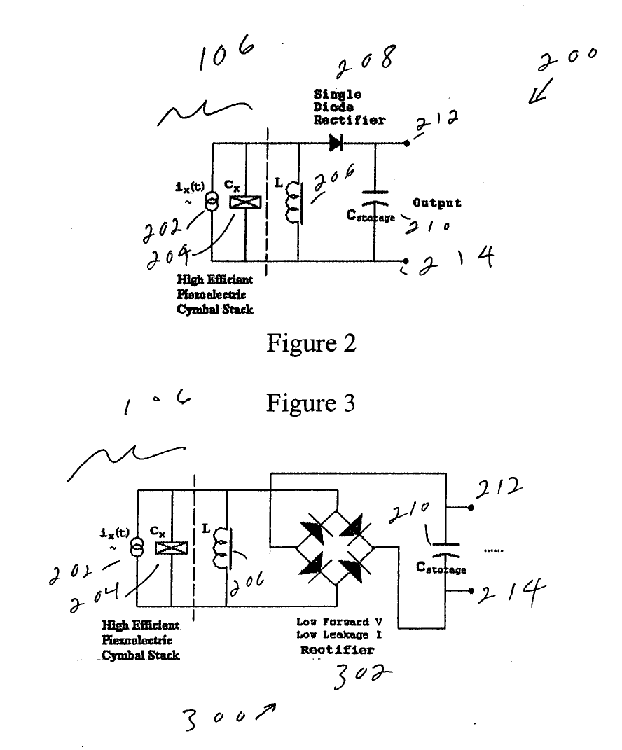

FIG. 2 shows a first circuit 200 incorporating the energy harvesting device 100. In the circuit diagram of FIG. 2, the cymbal stack 106 is represented by an electrical circuit comprising a current source 202 and a capacitor 204. Connected in parallel across the output of the cymbal stack 106 is an inductor 206. A single diode rectifier 208, a storage capacitor 210 and output electrodes 212, 214 complete the circ 200.

FIG. 3 shows a second circuit 300 incorporating the energy harvesting device 100. The single diode rectifier 208 is replaced with a low forward voltage, low leakage current rectifier 302.

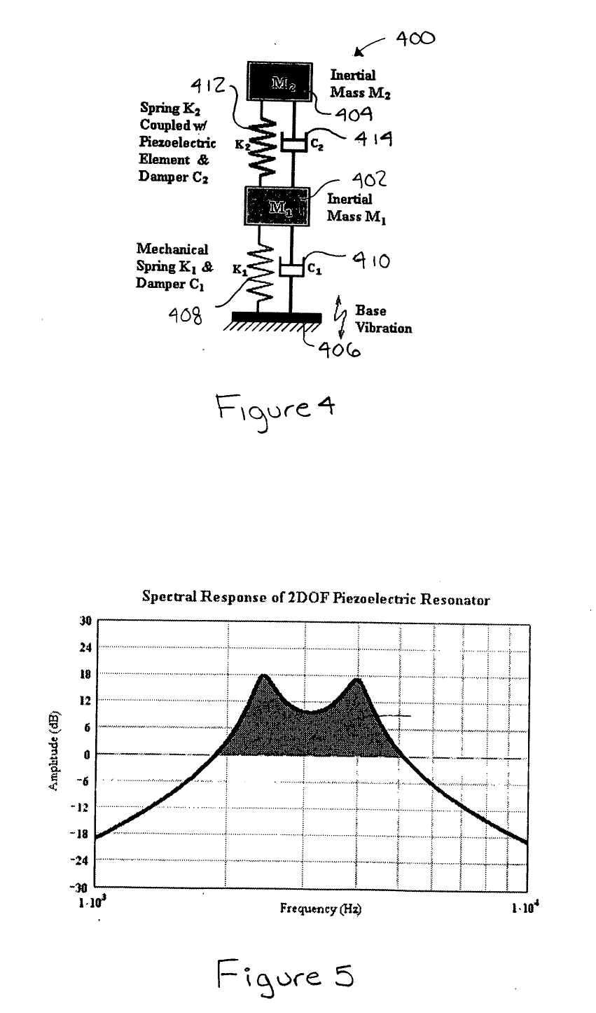

Referring to FIGS. 4-5, a multiple degree of freedom dynamic harvesting system, such as a two degree of freedom system (2DOF) piezoelectric resonator or device 400, is shown that has a wide band peak. As seen in FIG. 4, the system 400 includes a first inertial mass 402 and a second inertial mass 404. Between a base 406 of the device 400 and the first mass 402 is a first spring element 408 and a first damper 410. Between the first mass 402 and the second mass 404 is a second spring element 412 and a second damper 414, so that the piezoelectric element (described below) is stressed whenever the second spring element 412 is stressed. The first and second masses 402 and 404 are attached to the first and second spring elements 408 and 412, respectively. As seen in FIG. 5, there are two resonance peaks 502 and 504 created by the 2DOF system 400. Once the two resonance peaks 502 and 504 are tuned close to each other, the resulting response from the piezoelectric element of the harvester is a much wider resonant range or band of high efficiency compared to a SDOF system. The solid curve of FIG. 5 is the projected spectral response from the piezoelectric element which is coupled with the second spring element 412. The bandwidth of the 2DOF system 400 could be as wide was 2-3 kHz.

FIGS. 6-9 are examples of harvesting devices that use the 2DOF system 400 of FIGS. 4 and 5. Referring to FIG. 6, a harvesting device 600 is a tension-compression mode cymbal design similar to the harvesting device 100 of the first embodiment, except the harvesting device 600 incorporates the 2DOF system 400. Specifically, a piezoelectric element or plate 601 of the harvesting device 600 is disposed between cymbal-shaped caps or spring elements 612. Another spring element 608 is connected to the base 606 of the device 600. A first mass 602 is located below the cymbal-shaped spring element 612 such that the piezoelectric element 601 is bonded between the first mass 602 and the second spring element 612. A second mass 604 is disposed on top of the cymbal-shaped spring elements 612.

Referring to FIG. 7, a harvesting device 700 is a compression mode piezoelectric plate design that has a first spring element 708 connected to a base 706 of the device 700. A piezoelectric element 701 is bonded between a first mass 702 and a second compression spring element 712. A second mass 704 is disposed on top of the second spring element 712.

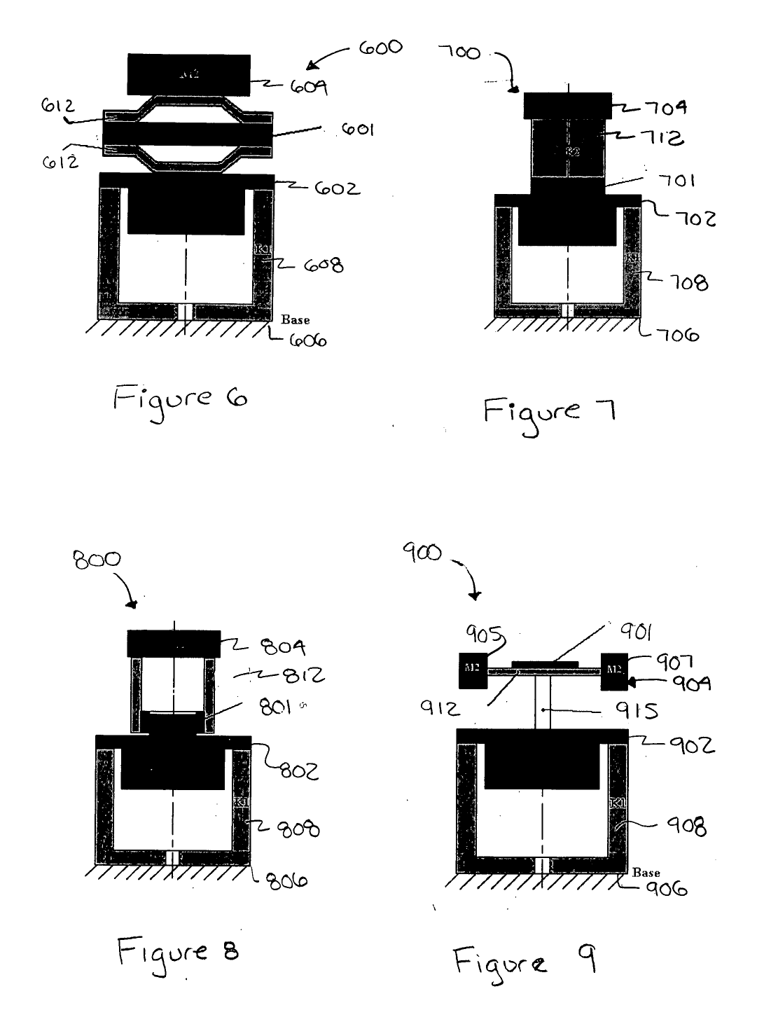

Referring to FIG. 8, a harvesting device 800 is a shear mode piezoelectric ring design that includes a first spring element 808 disposed on a base 806 of the device 800. A first mass 802 is disposed on top of the first spring element 808. A piezoelectric ring element 801 is disposed around a portion of the first mass 802 inside of a second spring element 812, such that piezoelectric ring element 801 is bonded between the first mass 802 and the second spring 812. A second mass 804 is disposed on top of the second spring element 812.

Referring to FIG. 9, a harvesting device 900 is a bending mode flexural beam design that includes a base 906 with a first spring element 908 disposed thereon. A first mass 902 is disposed on the first spring element 908. Between the first mass 902 and a cantilever beam second spring element 912 is a supporting post 915. First and second parts 905 and 907 of a second mass 904 are disposed on opposite ends of the second spring element 912. A piezoelectric element or plate 901 is bonded to the second spring element 912.

The piezoelectric elements 601, 701, 801 and 901 can be made of any piezoelectric material, including a single crystalline, such as a diamond, or a multi-crystalline, such as a ceramic.

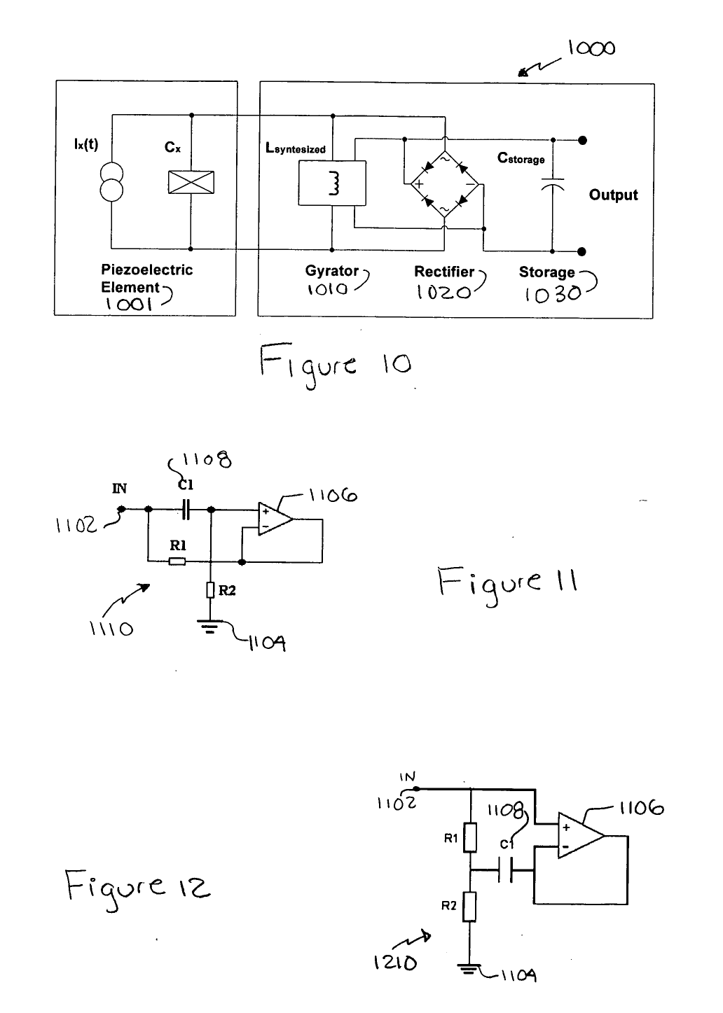

Referring to FIGS. 10-12, a harvesting device 1000 is similar to the device 100 of FIGS. 2 and 3, except the device 1000 uses a synthesized inductor or gyrator 1010 instead of a conventional metal coil inductor. The gyrator 1010 is placed in parallel with the piezoelectric element (represented by circuit 1001) prior to the rectifier 1020 and 1030 storage circuitry. Because of the very high value inductor (in the hundreds of Henry) required to resonate at low frequencies, the use of a conventional metal inductor can be impractical. The gyrator 1010 is an electronic circuit that simulates an inductor. Therefore, the conventional heavy and bulky inductor can be replaced with a smaller lighter weight synthesized inductor.

FIGS. 11 and 12 represent two alternative circuits 1110 and 1210 for the gyrator 1010. The gyrator 1010 can synthesize very large inductors at very low power, which is preferably taken from the storage element. The input 1102 (IN) and the ground 1104 of both circuits 1110 and 1210 simulate the two ends of a conventional metal inductor. The gyrator 1010 is made of a ultra low power, low voltage operation amplifier 1106 along with a capacitor 1108 (C1) and uses the gyration effects to convert the capacitor into an inductor. The inductance at the input 1102 of both circuits 1110 and 1210 is L_{synthesized}=C1*R1*R2.

While particular embodiments have been chosen to illustrate the invention, it will be understood by those skilled in the art that various changes and modification can be made therein without departing from the scope of the invention as defined in the appended claims.

1. A piezoelectric vibration energy harvesting device, comprising:
a base;
a mass; and
a cymbal stack disposed between the base and the proof mass, the cymbal stack comprising:
a piezoelectric element disposed between the base and the proof mass;
a first cymbal-shaped cap disposed between the mass and the piezoelectric crystal; and
a second cymbal-shaped cap disposed between the piezoelectric crystal and the base.

2. A device of claim 1, wherein
the piezoelectric element is a relaxor crystal.

3. A device of claim 1, wherein
the first and second cymbal-shaped caps also function as electrodes and are connected to an electric output of the device.

4. A device of claim 1, wherein
the electrical output is connected to an inductor.

5. A device of claim 4, wherein
the piezoelectric element and the inductor have a resonance frequency which is tuned to be approximately equal to a mechanical resonance of the cymbal stack.

6. A device of claim 4, wherein
the inductor is a metal coil.

7. A device of claim 4, wherein
the inductor is a gyrator, said gyrator simulating an inductor coil by converting impedance into its inverse.

8. A piezoelectric vibration energy harvesting device, comprising:
a first mass;
a second mass;
a first spring element coupled to said first mass;
a second spring element coupled to said second mass; and
a piezoelectric element bonded between the first mass and the second spring,
whereby a stress applied to said second spring is applied to said piezoelectric element.

9. A device according to claim 8, wherein
said piezoelectric element is connected in parallel with an inductor.

10. A device according to claim 9, wherein
said inductor is a gyrator, said gyrator simulating an inductor coil by converting impedance into its inverse.

11. A device according to claim 8, wherein
said second spring element is a compression spring, and
said piezoelectric element being disposed on an end of said spring.

12. A device according to claim 8, wherein
said piezoelectric element is a ring disposed around a portion of said first mass and disposed inside of said second spring element.

13. A device according to claim 8, wherein
said second spring element includes a cantilever beam;
said piezoelectric element being disposed on said beam; and
said second mass being connected to an end of said beam.

14. A device according to claim 8, wherein
said second spring element includes first and second cymbal-shaped caps, and
said piezoelectric element being disposed between said first and second caps.
